(19) United States
(12) Patent Application Publication
(10) Pub. No.: US 2025/0222565 A1
(43) Pub. Date: Jul. 10, 2025

(54) SUBSTRATE ADSORPTION DEVICE

(71) Applicant: Samsung Display Co., LTD., Yongin-si (KR)

(72) Inventor: Dong Won YI, Yongin-si (KR)

(73) Assignee: Samsung Display Co., LTD., Yongin-si (KR)

(21) Appl. No.: 18/802,175

(22) Filed: Aug. 13, 2024

(30) Foreign Application Priority Data
Jan. 8, 2024 (KR) 10-2024-0002781

(51) Int. Cl. B25B 11/00; H01L 21/673

(52) U.S. Cl. CPC B25B 11/005; H01L 21/6734

(57) ABSTRACT

A substrate adsorption device may include a stage including first adsorption holes and an insert port, and allowing a product to be placed on an upper surface of the stage; and a mask having a shape substantially identical to a shape of the product, and including second adsorption holes. In case that the mask is inserted into the stage along the insert port, the second adsorption holes may be aligned with some of the first adsorption holes in a plan view.

### CROSS-REFERENCE TO RELATED APPLICATION

The application claims priority to and benefits of Korean patent application number 10-2024-0002781 under 35 U.S.C. § 119, filed on Jan. 8, 2024 in the Korean Intellectual Property Office (KIPO), the entire disclosure of which is incorporated herein by reference.

### BACKGROUND

### 1. Technical Field

Various embodiments of the disclosure relate to a substrate adsorption device.

### 2. Description of Related Art

With the development of information technology, the importance of a display device, which is a connection medium between a user and information, has been emphasized. Owing to the importance of display devices, the use of various kinds of display devices, such as a liquid crystal display device and an organic light-emitting display device, has increased.

A process of fabricating a display device may be performed after a substrate is fastened to a stage. As the size of the display devices diversifies, the size and shape of substrates for display devices are also becoming increasingly diverse. If the stage is changed for each substrate for display devices, it may necessitate labor efforts for setting the planarization of the stage and incur costs for stage replacement.

### SUMMARY

Various embodiments of the disclosure are directed to a substrate adsorption device capable of employing substrates having various sizes and shapes.

An embodiment of the disclosure may provide a substrate adsorption device including a stage including first adsorption holes and an insert port, and having an upper surface allowing a product to be placed on the upper surface; and a mask having a shape substantially identical to a shape of the product, and including second adsorption holes. In case that the mask is inserted into the stage along the insert port, the second adsorption holes may be aligned with some of the first adsorption holes in a plan view.

In an embodiment, the first adsorption holes may be positioned in the upper surface of the stage, and the first adsorption holes may communicate with an internal space of the insert port.

In an embodiment, the stage further may include a vacuum hole. The vacuum hole may be positioned in a lower surface of the stage, and the vacuum hole may communicate with an internal space of the insert port.

In an embodiment, holes of the first adsorption holes that are aligned with the second adsorption holes may form a vacuum region corresponding to the shape of the product.

In an embodiment, the size of each of the first adsorption holes may be substantially identical to the size of each of the second adsorption holes. Each arrangement interval between the first adsorption holes may be substantially identical to each arrangement interval between the second adsorption holes.

In an embodiment, the first adsorption holes may be arranged in parallel in a first direction and a second direction.

In an embodiment, the insert port may be formed by etching in the first direction.

In an embodiment, the first adsorption holes and the second adsorption holes may be formed by etching in a third direction perpendicular to the first direction and the second direction.

An embodiment of the disclosure may provide a substrate adsorption device including a stage including adsorption holes and an insert port, and allowing a product to be placed on an upper surface of the stage; and a mask including an opening having a shape substantially identical to a shape of the product. In case that the mask is inserted into the stage along the insert port, the opening may overlap the adsorption holes in a plan view.

In an embodiment, the adsorption holes may be positioned in the upper surface of the stage, and the adsorption holes may communicate with an internal space of the insert port. In an embodiment, the stage may further include a vacuum hole. The vacuum hole may be positioned in a lower surface of the stage, and the vacuum hole may communicate with an internal space of the insert port.

In an embodiment, the substrate adsorption device may further include a vacuum pump that suctions gas from the stage. The vacuum hole may be connected to the vacuum pump.

In an embodiment, holes of the adsorption holes that overlap the opening in a plan view may be open and form a vacuum region corresponding to the shape of the product.

In an embodiment, holes of the adsorption holes that do not overlap the opening in a plan view may be closed.

In an embodiment, the adsorption holes may be arranged in parallel in a first direction and a second direction.

In an embodiment, the insert port may be formed by etching in the first direction.

In an embodiment, the stage may further include a fastening hole formed by etching in the first direction. The substrate adsorption device may further include a stopper fitted into the fastening hole.

In an embodiment, the adsorption holes and the opening may be formed by etching in a third direction perpendicular to the first direction and the second direction.

In an embodiment, the stage may further include a rail formed in the first direction in an internal space of the insert port. The mask may further include a roller that rolls on the rail.

In an embodiment, the rail may have a slant on an end of the rail in the first direction in the internal space of the insert port.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a substrate adsorption device in accordance with an embodiment of the disclosure.

FIG. 2 is a schematic plan view of a stage of FIG. 1.

FIG. 3 is a schematic sectional view of the stage taken along line I-I′ illustrated in FIG. 2.

FIG. 4 is a schematic plan view of the stage with a mask inserted thereinto.

FIG. 5 is a schematic sectional view of the stage taken along line II-II′ illustrated in FIG. 4.

FIG. 6 is a schematic perspective view of a substrate adsorption device in accordance with an embodiment of the disclosure.

FIGS. 7 and 8 are schematic plan views each illustrating a stage with a mask inserted thereinto in accordance with embodiments.

FIG. 9 is a schematic sectional view of the stage taken along line III-III′ illustrated in FIG. 8.

FIG. 10 is a schematic perspective view illustrating a stage in accordance with an embodiment of the disclosure.

FIG. 11 is a schematic plan view of the stage illustrated in FIG. 10.

FIG. 12 is a schematic sectional view of the stage taken along line IV-IV′ illustrated in FIG. 11.

### DETAILED DESCRIPTION OF THE EMBODIMENTS

Hereinafter, embodiments of the disclosure will be described in detail with reference to the attached drawings, such that those skilled in the art can readily implement the disclosure. The disclosure may be embodied in various different forms without being limited to embodiments to be described herein.

In the drawings, portions unrelated to the disclosure may have been omitted to clarify the description of the disclosure, and the same reference numerals may be used throughout the different drawings to designate the same or similar components.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be directly on the second part or a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be directly under the second part or a third part may intervene between them.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

In this disclosure, in case that two elements “communicate” with each other, the two elements may be connected to each other such that a passage may be formed through the two elements.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

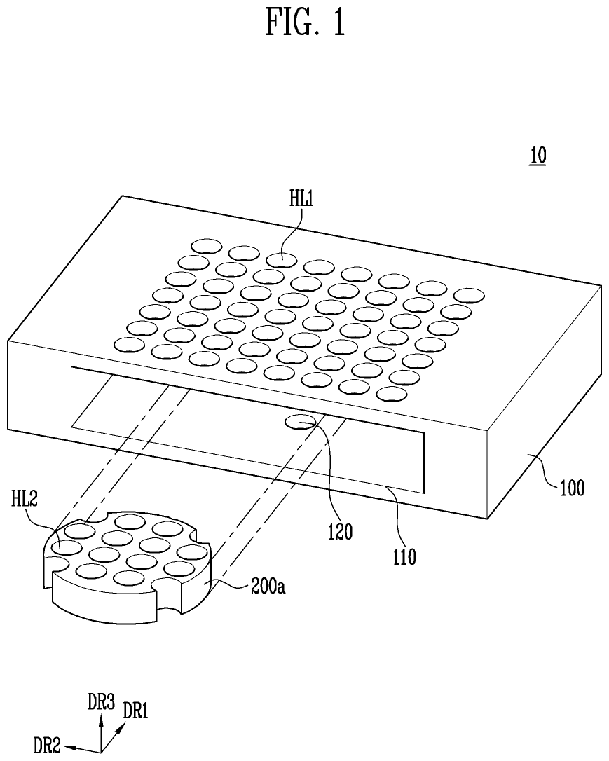

FIG. 1 is a schematic perspective view of a substrate adsorption device 10 in accordance with an embodiment of the disclosure.

Referring to FIG. 1, the substrate adsorption device 10 in accordance with an embodiment of the disclosure may include a stage 100 and a mask 200a.

The stage 100 may provide space in which a product may be placed. For example, the product may be a substrate for display devices.

The product may be placed on an upper surface of the stage 100. For example, in the case where the product is a substrate for display devices, the substrate may be placed on the upper surface of the stage 100, and a process of forming a thin film or a pattern on the substrate, a process of mounting an electronic component on the substrate, or a process of moving the substrate may be performed.

The stage 100 may include first adsorption holes HL1, an insert port 110, and a vacuum hole 120. The first adsorption holes HL1 may be arranged in the upper surface of the stage 100 in a first direction or a second direction. The first adsorption holes HL1 may be formed by etching in a third direction. The first direction, the second direction, and the third direction may be directions perpendicular to each other. The third direction may be a direction perpendicular to the first direction and the second direction.

The insert port 110 may be formed in a side surface of the stage 100 by etching in the first direction. Internal space of the insert port 110 may communicate with each of the first adsorption holes HL1.

The vacuum hole 120 may be formed in a lower surface of the stage 100 by etching in the third direction. The vacuum hole 120 may communicate with the internal space of the insert port 110.

In an embodiment, the first adsorption holes HL1, the internal space of the insert port 110, and the vacuum hole 120 may communicate with each other, thus forming a passage making it possible to discharge gas out of internal space of the stage 100. The internal space of the stage 100 may refer to the same space as the internal space of the insert port 110 that may be formed by etching in the first direction.

In an embodiment, the substrate adsorption device 10 may further include a vacuum pump (not illustrated) configured to suction gas from the internal space of the stage 100. The vacuum pump (not illustrated) may be connected to the vacuum hole 120 to discharge gas from the internal space of the stage 100 to the outside.

The mask 200a may have a shape substantially identical or similar to the product to be placed on the upper surface of the stage 100. The mask 200a may be inserted into the stage 100 along the insert port 110.

The mask 200a may include second adsorption holes HL2. The second adsorption holes HL2 may be arranged in the upper surface of the mask 200a in the first direction or the second direction. The second adsorption holes HL2 may be formed by etching in the third direction.

The size of each of the first adsorption holes HL1 may be the same as that of each of the second adsorption holes HL2. The arrangement intervals between the first adsorption holes HL1 may be the same as those between the second adsorption holes HL2.

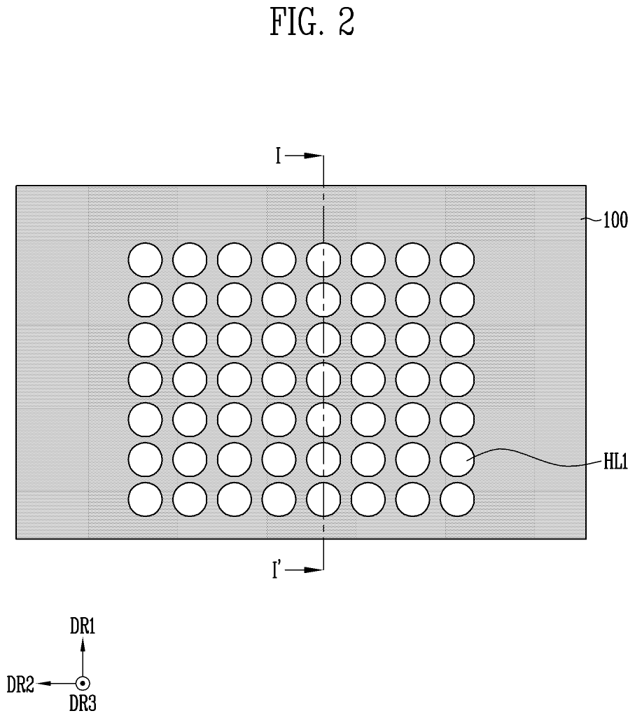

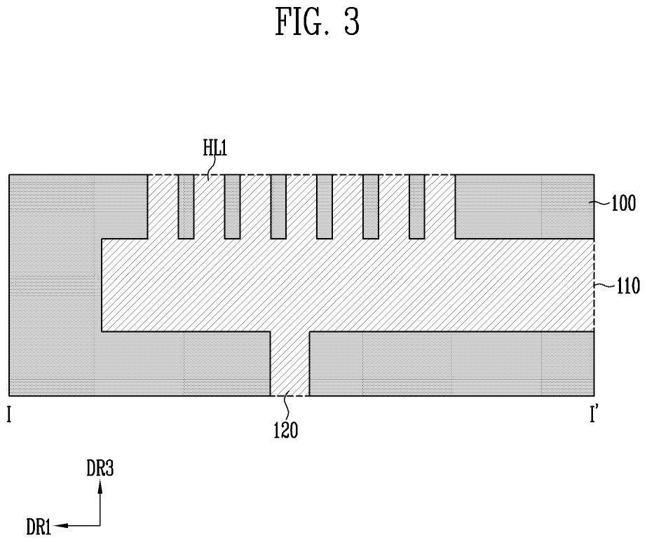

FIG. 2 is a schematic plan view of the stage 100 of FIG. 1. FIG. 3 is a schematic sectional view of the stage 100 taken along line I-I′ illustrated in FIG. 2.

Referring to FIG. 2, there are illustrated first adsorption holes HL1 of the stage 100. Referring to FIG. 3, the first adsorption holes HL1, the internal space of the insert port 110, and the vacuum hole 120 may communicate with each other. As the first adsorption holes HL1, the internal space of the insert port 110, and the vacuum hole 120 may communicate with each other, the passage making it possible to discharge gas out of the internal space of the stage 100 may be formed.

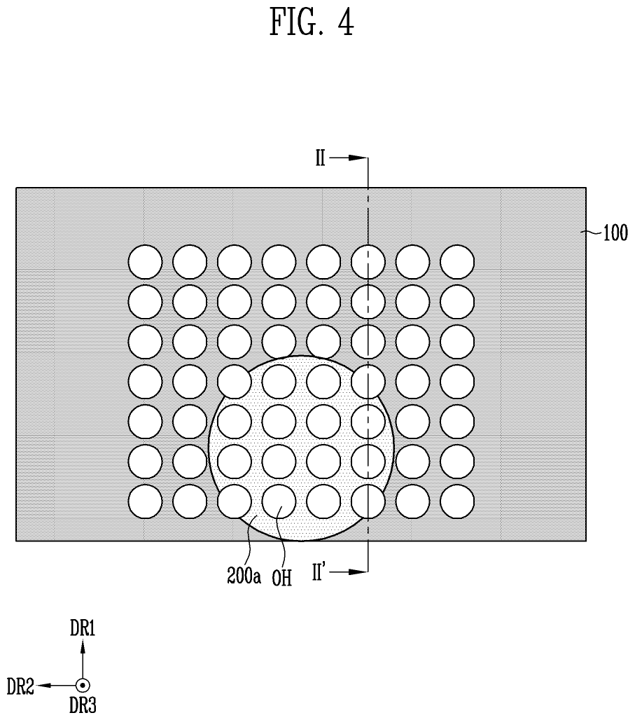

FIG. 4 is a schematic plan view of the stage 100 with the mask 200a inserted thereinto.

Referring to FIGS. 1 and 4, the mask 200a may be inserted into the stage 100 along the insert port 110 formed by etching in the first direction. In case that the mask 200a is inserted into the stage 100, the second adsorption holes HL2 of the mask 200a may be aligned with some of the first adsorption holes HL1 of the stage 100, in a plan view.

Accordingly, the second adsorption holes HL2 and some of the first adsorption holes HL1 that are aligned with the second adsorption holes HL2 may form open holes OH. The open holes OH may communicate with the internal space of the insert port 110 and the vacuum hole 120, thus forming a passage making it possible to discharge gas out of the internal space of the stage 100.

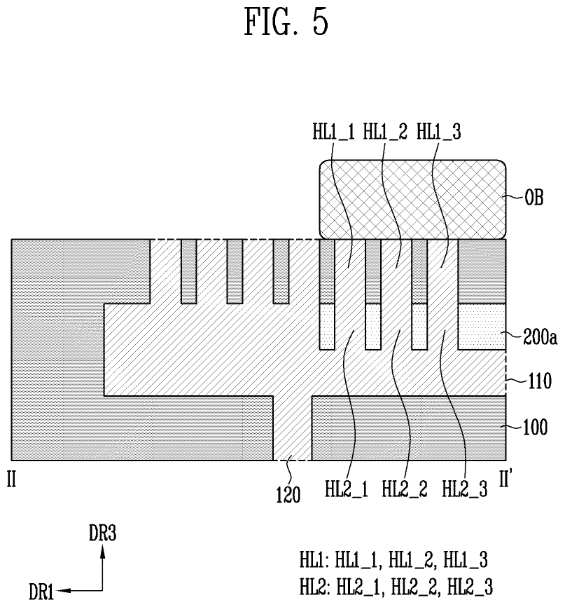

FIG. 5 is a schematic sectional view of the stage 100 taken along line II-II′ illustrated in FIG. 4.

Referring to FIG. 5, the mask 200a may be inserted into the stage 100, and a product OB may be placed on the upper surface of the stage 100.

The mask 200a may have a shape substantially identical or similar to that of the product OB.

The second adsorption holes HL2 may respectively communicate with some of the first adsorption holes HL1, thus forming passages. For example, a first adsorption hole HL1_1 may communicate with a second adsorption hole HL2_1, a first adsorption hole HL1_2 may communicate with a second adsorption hole HL2_2, and a third adsorption hole HL1_3 may communicate with a second adsorption hole HL2_3, thereby forming the passages. For example, in a plan view, some of the first adsorption hole HL1 may be aligned with the second adsorption hole HL2.

The product OB may be placed over the passages formed by connection of the respective second adsorption holes HL2 and corresponding some of the first adsorption holes HL1. In case that gas is discharged from the internal stage of the stage 100 through the vacuum hole 120, a vacuum region corresponding to the shape of the product OB may be formed.

For example, among the first adsorption holes HL1, the holes HL1_1 to HL1_3 aligned with the second adsorption holes HL2 may form the vacuum region corresponding to the shape of the product OB.

Although three second adsorption holes HL2_1 to HL2_3 are illustrated in FIG. 5, the number of second adsorption holes HL2 may be changed depending on the shape of the product OB. Furthermore, as the number of second adsorption holes HL2 may be changed, the number of holes aligned with the second adsorption holes HL2 among the first adsorption holes HL1 may be changed.

The mask 200a having a shape substantially identical or similar to that of the product OB can be inserted into the stage 100 without replacement of the stage 100 on which the product OB is placed. Accordingly, even if the shape of the product OB is changed, the substrate adsorption device can adsorb the product OB while maintaining the planarization of the stage 100.

Since the planarization of the stage 100 may be maintained while the product OB may be adsorbed even if the shape of the product OB is changed, labor efforts for setting the planarization of the stage 100 and costs for replacing the uppermost plate of the stage 100 each time the product OB is changed in shape may be reduced.

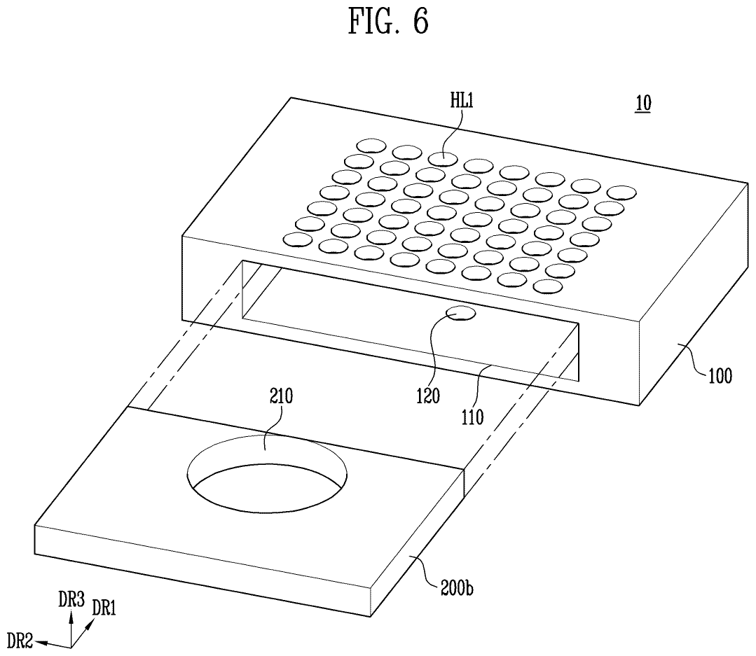

FIG. 6 is a schematic perspective view of a substrate adsorption device 10 in accordance with an embodiment of the disclosure.

Referring to FIG. 6, the substrate adsorption device 10 in accordance with an embodiment of the disclosure may include a stage 100 and a mask 200b. The stage 100 of FIG. 6 may be substantially identical or similar to the stage 100 of FIG. 1; therefore, redundant explanation thereof will be omitted.

The mask 200b may have an opening 210. The opening 210 may have a shape substantially identical or similar to that of the product to be placed on the upper surface of the stage 100. The opening 210 may be formed by etching in the third direction.

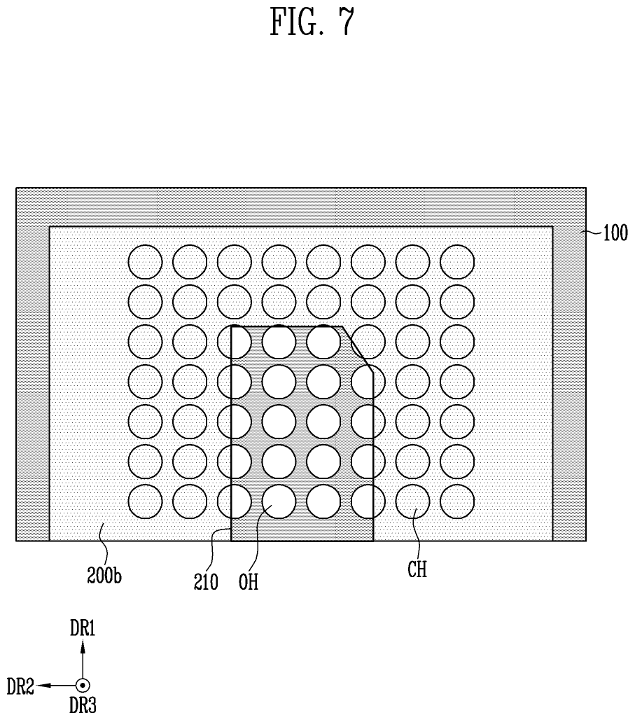

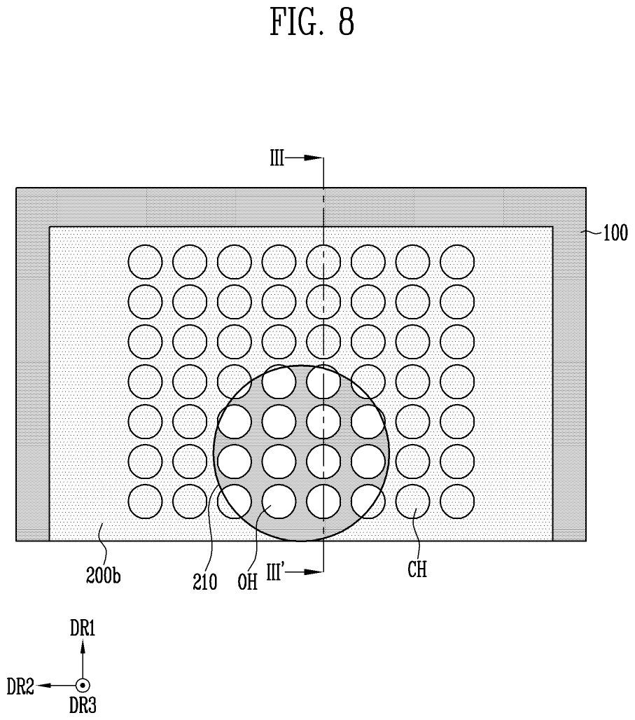

FIGS. 7 and 8 are schematic plan views each illustrating a stage with a mask inserted thereinto in accordance with embodiments.

Referring to FIGS. 6 to 8, the mask 200b may be inserted into the stage 100 along the insert port 110 formed by etching in the first direction. Referring to FIGS. 7 and 8, there are illustrated masks 200b each having an opening 210 corresponding to the shape of the product OB. Although FIG. 7 illustrates an opening 210 corresponding to a product OB having a polygonal shape and FIG. 8 illustrates an opening 210 corresponding to a product OB having a circular shape, the disclosure is not limited thereto. The mask 200b may include openings 210 corresponding to products OB having various shapes.

In case that the mask 200b is inserted into the stage 100, the opening 210 of the mask 200b may overlap some of the first adsorption holes HL1 of the stage 100 in a plan view.

In more detail, some of the first adsorption holes HL1 may overlap the opening 210, thus forming open holes OH. The open holes OH may communicate with the internal space of the insert port 110 and the vacuum hole 120, thus forming a passage making it possible to discharge gas out of the internal space of the stage 100. For example, among the first adsorption holes HL1, the holes overlapping the opening 210 may be open, thus forming a vacuum region corresponding to the shape of the product OB.

Some of the first absorption holes HL1 do not overlap the opening 210, thus forming closed holes CH. The closed holes CH may not communicate with the internal space of the insert port 110 and the vacuum hole 120. For example, among the first adsorption holes HL1, the holes that do not the opening 210 may be closed.

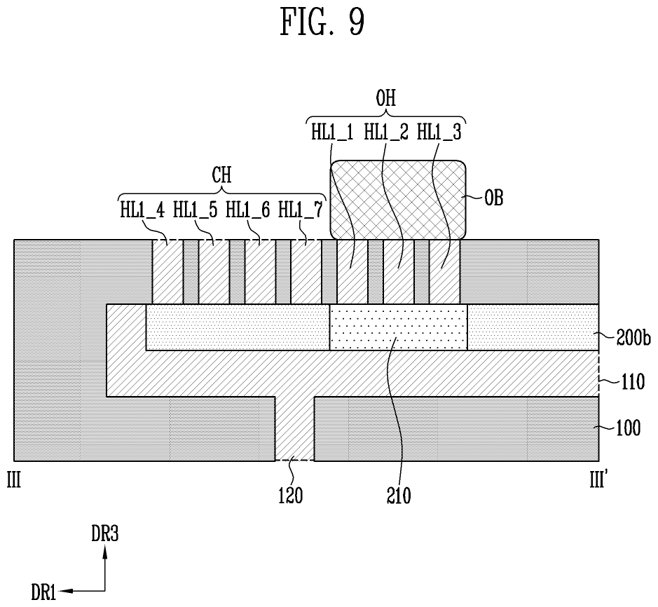

FIG. 9 is a schematic sectional view of the stage 100 taken along line III-III′ illustrated in FIG. 8.

Referring to FIG. 9, the mask 200b may be inserted into the stage 100, and the product OB may be placed on the upper surface of the stage 100.

The mask 200b may have a shape substantially identical or similar to that of the product OB.

The opening 210 may communicate with the first adsorption holes HL1, thus forming a passage. For example, some holes HL1_1 to HL1_3 among the first adsorption holes HL1 may be open holes OH, and some holes HL1_4 to HL1_7 among the first adsorption holes HL1 may be closed holes CH.

The product OB may be placed over the passages formed by the overlap of the opening 210 and some holes HL1_1 to HL1_3 among the first adsorption holes HL1. In case that gas is discharged from the internal stage of the stage 100 through the vacuum hole 120, a vacuum region corresponding to the shape of the product OB may be formed.

For example, the opening 210 and some holes HL1_1 to HL1_3 among the first adsorption holes HL1 may form the vacuum region corresponding to the shape of the product OB.

In FIG. 9, the mask 200b having the opening 210 depicted in FIG. 8 is inserted, so that some holes HL1_1 to HL1_3 among the first adsorption holes HL1 are open holes OH, and some holes HL1_4 to HL1_7 among the first adsorption holes HL1 are closed holes CH. However, the disclosure is not limited to the aforementioned example, and the shape of the opening 210 may be changed depending on the shape of the product OB. Consequently, the number of open holes OH and closed holes CH may be changed.

For instance, in case that the mask 200b having the opening 210 depicted in FIG. 7 is inserted, some holes HL1_1 to HL1_3 and HL1_6 to HL1_7 among the first adsorption holes may be open, and some holes HL1_4 and HL1_5 among the first adsorption holes may be closed. For example, as the mask 200b having the opening 210 with a shape substantially identical or similar to that of the product OB may be inserted into the stage 100 without replacement of the stage 100 on which the product OB is placed, opening and closing of the first adsorption holes HL1 may be controlled according to the shape of the product OB.

Since the planarization of the stage 100 may be maintained while the product OB is adsorbed even if the shape of the product OB is changed, labor efforts for setting the planarization of the stage 100 and costs for replacing the uppermost plate of the stage 100 each time the product OB is changed in shape may be reduced.

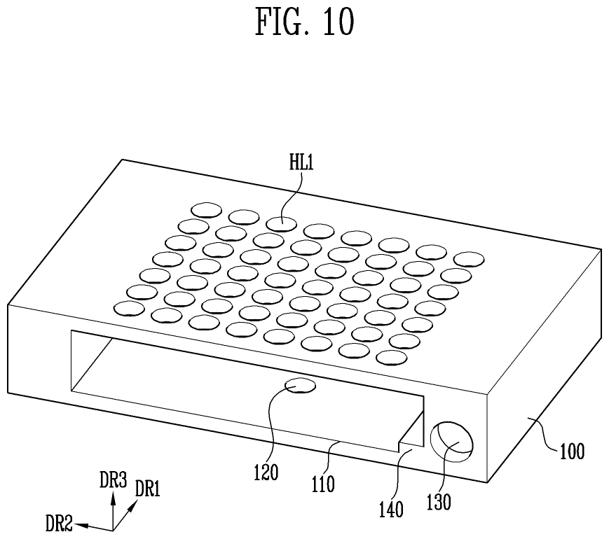

FIG. 10 is a schematic perspective view illustrating a stage 100 in accordance with an embodiment of the disclosure.

Referring to FIG. 10, there is illustrated the stage 100 including a fastening hole 130 and a rail 140. The stage 100 of FIG. 10 may be similar to the stage 100 of FIG. 1; therefore, redundant explanation thereof will be omitted.

The stage 100 may include the fastening hole 130 formed by etching in the first direction. The fastening hole 130 may be fitted with a stopper (not shown) to prevent external gas from being drawn into the stage 100.

Referring to FIG. 1, the substrate adsorption device 10 may further include the stopper (not shown). In an embodiment, in case that the mask 200a is inserted into the stage 100, the stopper (not shown) may be fitted into the fastening hole 130.

The stage 100 may further include the rail 140 formed in the internal space of the insert port 110 in the first direction. The mask 200a may further include a roller (not shown) that rolls on the rail 140.

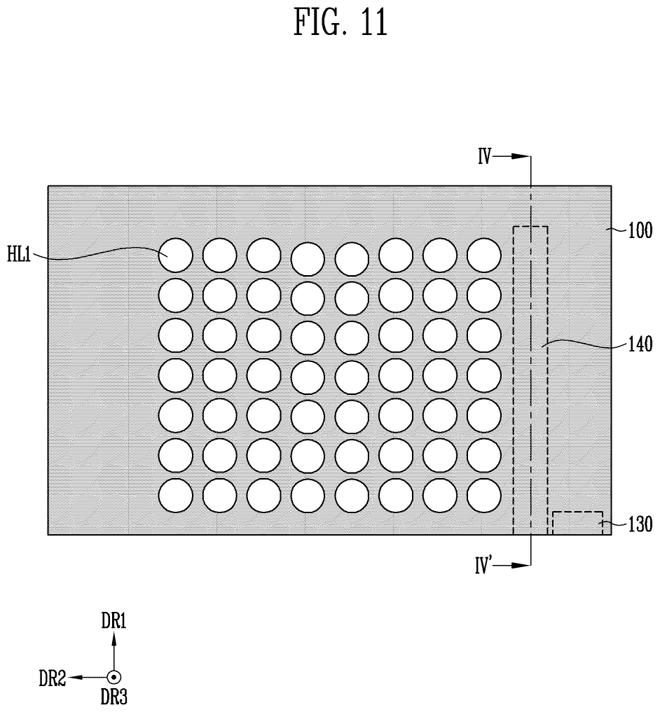

FIG. 11 is a schematic plan view of the stage 100 illustrated in FIG. 10.

Referring to FIG. 11, there is illustrated the stage 100 including the first adsorption holes HL1, the fastening hole 130, and the rail 140. In a plan view, the first adsorption holes HL1, the fastening hole 130, and the rail 140 may all be spaced apart from each other.

Although in FIGS. 10 and 11 there is illustrated the stage 100 including one fastening hole 130 and one rail 140, the disclosure is not limited thereto, and the stage 100 may include one or more fastening holes and one or more rails.

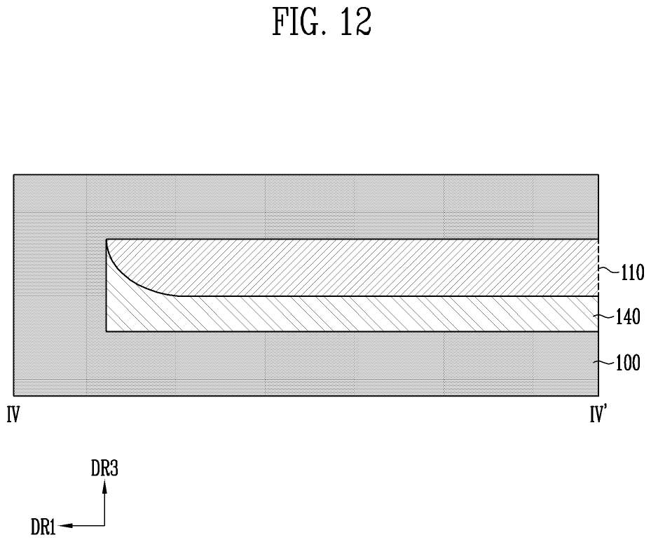

FIG. 12 is a schematic sectional view of the stage 100 taken along line IV-IV′ illustrated in FIG. 11. Referring to FIGS. 10 and 12, there is a sectional view of the stage 100 including the rail 140.

In an embodiment, the rail 140 may have a slant on an end thereof in the first direction in the internal space of the insert port 110. In the case where the mask 200a includes the roller (not shown), the roller (not shown) rolls along the slant of the rail 140, thus allowing the mask 200a to be readily disposed on an upper end of the internal space of the insert port 110.

In accordance with a substrate adsorption device according to the disclosure, labor efforts for setting the planarization of a state and costs for stage replacement may be reduced.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A substrate adsorption device comprising:
a stage including first adsorption holes and an insert port, and having an upper surface allowing a product to be placed on the upper surface; and
a mask having a shape substantially identical to a shape of the product, and including second adsorption holes,
wherein in case that the mask is inserted into the stage along the insert port, the second adsorption holes are aligned with some of the first adsorption holes in a plan view.

2. The substrate adsorption device according to claim 1, wherein
the first adsorption holes are positioned in the upper surface of the stage, and
the first adsorption holes communicate with an internal space of the insert port.

3. The substrate adsorption device according to claim 1, wherein
the stage further includes a vacuum hole,
the vacuum hole is positioned in a lower surface of the stage, and
the vacuum hole communicates with an internal space of the insert port.

4. The substrate adsorption device according to claim 1, wherein holes of the first adsorption holes that are aligned with the second adsorption holes form a vacuum region corresponding to the shape of the product.

5. The substrate adsorption device according to claim 1, wherein
a size of each of the first adsorption holes is substantially identical to a size of each of the second adsorption holes, and
each arrangement interval between the first adsorption holes is substantially identical to each arrangement interval between the second adsorption holes.

6. The substrate adsorption device according to claim 1, wherein the first adsorption holes are arranged in parallel in a first direction and a second direction.

7. The substrate adsorption device according to claim 6, wherein the insert port is formed by etching in the first direction.

8. The substrate adsorption device according to claim 6, wherein the first adsorption holes and the second adsorption holes are formed by etching in a third direction perpendicular to the first direction and the second direction.

9. A substrate adsorption device comprising:
a stage including adsorption holes and an insert port, and allowing a product to be placed on an upper surface of the stage; and
a mask including an opening having a shape substantially identical to a shape of the product,
wherein in case that the mask is inserted into the stage along the insert port, the opening overlaps the adsorption holes in a plan view.

10. The substrate adsorption device according to claim 9, wherein
the adsorption holes are positioned in the upper surface of the stage, and
the adsorption holes communicate with an internal space of the insert port.

11. The substrate adsorption device according to claim 9, wherein
the stage further includes a vacuum hole,
the vacuum hole is positioned in a lower surface of the stage, and
the vacuum hole communicates with an internal space of the insert port.

12. The substrate adsorption device according to claim 11, further comprising:
a vacuum pump that suctions gas from the stage,
wherein the vacuum hole is connected to the vacuum pump.

13. The substrate adsorption device according to claim 9, wherein holes of the adsorption holes that overlap the opening in a plan view are open and form a vacuum region corresponding to the shape of the product.

14. The substrate adsorption device according to claim 9, wherein holes of the adsorption holes that do not overlap the opening in a plan view are closed.

15. The substrate adsorption device according to claim 9, wherein the adsorption holes are arranged in parallel in a first direction and a second direction.

16. The substrate adsorption device according to claim 15, wherein the insert port is formed by etching in the first direction.

17. The substrate adsorption device according to claim 16, wherein
the stage further includes a fastening hole formed by etching in the first direction, and
the substrate adsorption device further comprises a stopper fitted into the fastening hole.

18. The substrate adsorption device according to claim 15, wherein the adsorption holes and the opening are formed by etching in a third direction perpendicular to the first direction and the second direction.

19. The substrate adsorption device according to claim 15, wherein
the stage further comprises a rail formed in the first direction in an internal space of the insert port, and
the mask further comprises a roller that rolls on the rail.

20. The substrate adsorption device according to claim 19, wherein the rail has a slant on an end of the rail in the first direction in the internal space of the insert port.
